(19) United States
(12) Patent Application Publication
(10) Pub. No.: US 2026/0255841 A1
(43) Pub. Date: Aug. 27, 2026

(54) SEMICONDUCTOR MANUFACTURING METHOD FOR IN-SITU FORMING METAL MESH GRID USING SHADOW MASK AND SEMICONDUCTOR DEVICE FORMED BY SAME METHOD

(71) Applicant: GACHON UNIVERSITY INDUSTRY-ACADEMIC COOPERATION FOUNDATION, Seongnam-si (KR)

(72) Inventors: Sang Jik KWON, Seoul (KR); Eou Sik CHO, Seongnam-si (KR); Yong Min JEON, Seoul (KR)

(21) Appl. No.: 19/397,381

(22) Filed: Nov. 21, 2025

Related U.S. Application Data
(63) Continuation of application No. PCT/KR2024/006805, filed on May 20, 2024.

(30) Foreign Application Priority Data
May 23, 2023 (KR) 10-2023-0066336

(51) Int. Cl. H10K 59/80; H10K 59/12; H10K 71/60

(52) U.S. Cl. CPC H10K 59/80515; H10K 59/1201; H10K 59/80517; H10K 59/80521; H10K 59/80523; H10K 71/60

(57) ABSTRACT

A semiconductor device includes: a transparent base member; a bottom grid electrode formed on the transparent base member; a light-emitting organic layer formed on the bottom grid electrode; and a top grid electrode formed on the light-emitting organic layer. At least one of the bottom grid electrode or the top grid electrode is a mesh-type electrode, and at least one of the bottom grid electrode or the top grid electrode includes a plurality of first portions having a first thickness and forming a grid point portion and a second portion having a second thickness smaller than the first thickness and connecting the first portions.

### CROSS-REFERENCE TO RELATED APPLICATIONS

This application is a continuation of PCT/KR2024/006805 filed on May 20, 2024, which claims priority from Korean Patent Application No. 10-2023-0066336 filed on May 23, 2023. The aforementioned applications are incorporated herein by reference in their entireties.

### TECHNICAL FIELD

The present disclosure relates to a metal mesh grid formation technology, and more particularly, to a method of manufacturing a metal mesh grid electrode in which a metal material is formed in a mesh shape on a transparent base member to simultaneously secure excellent transmittance and conductivity, while also significantly simplifying the manufacturing process and reducing the process time.

### RELATED ART

The content described in this section merely provides background information on the present exemplary embodiment and does not constitute prior art.

The organic light emitting diode (OLED) is an important device applied to displays and smart lighting devices. An OLED includes an anode electrode and a cathode electrode respectively formed below and above organic layers used as the light-emitting layer, and the electrodes must be transparent in order to allow light to pass through. In the OLED, an active layer serving as the light-emitting layer is formed between an electron transporting layer (ETL) and a hole transporting layer (HTL), both of which are also made of organic materials. The cathode electrode and the anode electrode are respectively formed on the upper and lower portions of the organic layers to inject electrons and holes, and the electrode layers are made of transparent electrodes to allow light generated from the active layer to pass through. In the case of large-area OLEDs, the transparent electrode is combined with a metal grid.

In a bottom-emission OLED that emits light downward, the lower electrode must be transparent. In a top-emission OLED that emits light upward, the upper electrode must be transparent. In an OLED that emits light in both upward and downward directions, both electrodes must be transparent. As transparent electrodes, transparent conductive oxides (TCOs) such as ITO and AZO, or extremely thin metal films such as Al, Ag, Mg, Au, Cu, or MgAg alloys are generally used. Alternatively, conductive materials such as Ag nanowires or graphene may also be used. These transparent electrodes must have high optical transmittance and high electrical conductivity.

However, OLEDs applied to lighting devices have a large light-emitting area, ranging from several mm² to several cm². Therefore, when a thin transparent electrode is used, the resistance of the transparent electrode becomes high, which may increase the operating voltage of the OLED device due to IR voltage drop. In addition, heat generation due to I²R may shorten the lifetime of the device or cause instability in the emission spectrum, such as a broadening of the spectral width or a shift in the spectral peak.

As a solution to these problems, a metal grid electrode is formed by patterning a metal layer such as Ag, Al, or MgAg into a mesh shape having a width and thickness of several tens to hundreds of micrometers. However, existing methods use photolithography or lift-off processes for pattern formation, which must be performed before the formation of the organic material of the OLED device, thereby limiting their applicability. Moreover, since a separate patterning process is required, such methods suffer from issues of high cost.

### SUMMARY

An object of the present disclosure is to provide a method of manufacturing a metal mesh grid electrode, in which a metal material is deposited in a mesh form on a transparent base member or on an organic thin film of an OLED by an evaporation method using a shadow mask inside a vacuum deposition apparatus for manufacturing an OLED device, thereby achieving both transmittance and conductivity, while significantly simplifying the manufacturing process and reducing the process time.

Another object of the present disclosure is to provide a method in which, by forming the metal mesh grid electrode inside a vacuum chamber, at least one of an upper grid and/or a lower grid and a light-emitting organic device layer are formed in-situ within a single vacuum chamber entry.

A semiconductor device, comprises a transparent base member, a bottom grid electrode formed on the transparent base member, the bottom grid electrode being a mesh-type, a light-emitting organic layer formed on the mesh-type bottom grid electrode, and a top grid electrode formed on the light-emitting organic layer, the top grid electrode being a mesh type.

At least one of the bottom grid electrode and/or the top grid electrode comprises a plurality of first portions forming a grid and having a first thickness, and a second portion having a second thickness smaller than the first thickness and connecting the first portions.

At least one of the bottom grid electrode and/or the top grid electrode may have at least one pattern selected from a rectangular pattern, a diamond pattern, and a hexagonal pattern.

At least one of the bottom grid electrode and/or the top grid electrode may have an inclined surface at a boundary region between the first portions and the second portions.

A method of manufacturing a semiconductor device, comprises forming a bottom grid electrode on a transparent base member, the bottom grid electrode being a mesh-type; forming a light-emitting organic layer on the bottom grid electrode; and forming a top grid electrode on the light-emitting organic layer, the top grid electrode being a mesh-type.

At least one of the forming of the bottom grid electrode and/or the forming of the top grid electrode may be performed using a deposition process in which a metal material is deposited using a shadow mask having a mesh pattern.

At least one of the forming of the bottom grid electrode and/or the forming of the top grid electrode may be performed so as to comprise a plurality of first portions forming a grid and having a first thickness, and a second portion having a second thickness smaller than the first thickness and connecting the first portions.

The shadow mask having the mesh pattern may have a frame pattern for forming a grid electrode having at least one pattern selected from a rectangular structure, a diamond structure, and a honeycomb structure.

At least one of the forming of the bottom grid electrode and/or the forming of the top grid electrode may be performed in a state in which a metal evaporation direction of the metal material is controlled to be inclined with respect to the shadow mask.

At least one of the forming of the bottom grid electrode and/or the forming of the top grid electrode may be performed in a state in which at least one of a first surface, which includes at least one of the transparent base member and/or the light-emitting organic layer partially exposed by the shadow mask, and the shadow mask are spaced apart at a distance, such that at least one of the bottom grid electrode and/or the top grid electrode is formed on a region of the first surface covered by a connecting portion between patterns of the shadow mask.

According to exemplary embodiments of the present disclosure, by forming a metal mesh grid electrode inside a vacuum chamber, a process of forming at least one of an upper grid and/or a lower grid and a process of forming a light-emitting organic device layer may be performed in-situ within a single entry into the vacuum chamber.

Specifically, a manufacturing process for forming the metal mesh grid electrode may be implemented by controlling the deposition process in consideration of the specific environmental factors of the deposition process and the specialized structure of the shadow mask.

In the present disclosure, a metal grid having an interconnected mesh structure may be formed using a shadow mask without a separate etching process, thereby simplifying the manufacturing process and enabling the production of a metal grid at a lower process cost. In particular, the grid electrode portions formed through the open regions of the shadow mask and the grid electrode portions formed in the regions covered by the connecting portions between patterns of the closed regions of the shadow mask are deposited at an inclined angle, such that the grid electrode portions formed through the open regions may be connected to each other.

### BRIEF DESCRIPTION OF THE DRAWINGS

FIG. 1 is a conceptual diagram illustrating a semiconductor device having a metal grid according to exemplary embodiments of the present disclosure.

FIG. 2 is a flowchart illustrating a method of manufacturing a semiconductor device having a metal grid according to exemplary embodiments of the present disclosure.

FIG. 3 is a flowchart illustrating a method of manufacturing a semiconductor device having a metal grid according to other exemplary embodiments of the present disclosure.

FIG. 4 is a plan view showing a state in which mesh-type metal grid patterns are formed on a transparent base member according to exemplary embodiments of the present disclosure.

FIG. 5 is a plan view illustrating the structure of a mesh-type grid pattern of a shadow mask according to exemplary embodiments of the present disclosure.

FIG. 6 is a cross-sectional view illustrating examples of a method of depositing a metal material using a shadow mask inside a vacuum chamber to form a metal grid according to exemplary embodiments of the present disclosure.

FIGS. 7A, 7B and 7C are conceptual diagrams respectively illustrating examples of mesh shapes including rectangular, diamond, and hexagonal honeycomb structures according to exemplary embodiments of the present disclosure.

FIG. 8 is a plan view illustrating a pattern structure of a shadow mask for forming a hexagonal honeycomb metal grid according to exemplary embodiments of the present disclosure.

### DETAILED DESCRIPTION

For a clearer understanding of the features and advantages of the present disclosure, exemplary embodiments of the present disclosure will be described in detail with reference to the accompanying drawings. However, it should be understood that the present disclosure is not limited to particular embodiments disclosed herein but includes all modifications, equivalents, and alternatives falling within the spirit and scope of the present disclosure. In the drawings, similar or corresponding components may be designated by the same or similar reference numerals.

The terminologies including ordinals such as “first” and “second” designated for explaining various components in this specification are used to discriminate a component from the other ones but are not intended to be limiting to a specific component. For example, a second component may be referred to as a first component and, similarly, a first component may also be referred to as a second component without departing from the scope of the present disclosure. As used herein, the term “and/or” may include a presence of one or more of the associated listed items and any and all combinations of the listed items.

In the description of exemplary embodiments of the present disclosure, “at least one of A and B” may mean “at least one of A or B” or “at least one of combinations of one or more of A and B”. In addition, in the description of exemplary embodiments of the present disclosure, “one or more of A and B” may mean “one or more of A or B” or “one or more of combinations of one or more of A and B”.

When a component is referred to as being “connected” or “coupled” to another component, the component may be directly connected or coupled logically or physically to the other component or indirectly through an object therebetween. Contrarily, when a component is referred to as being “directly connected” or “directly coupled” to another component, it is to be understood that there is no intervening object between the components. Other words used to describe the relationship between elements should be interpreted in a similar fashion.

The terminologies are used herein for the purpose of describing particular exemplary embodiments only and are not intended to limit the present disclosure. The singular forms include plural referents as well unless the context clearly dictates otherwise. Also, the expressions “comprises,” “includes,” “constructed,” “configured” are used to refer a presence of a combination of stated features, numbers, processing steps, operations, elements, or components, but are not intended to preclude a presence or addition of another feature, number, processing step, operation, element, or component.

Unless defined otherwise, all terms used herein, including technical or scientific terms, have the same meaning as commonly understood by those of ordinary skill in the art to which the present disclosure pertains. Terms such as those defined in a commonly used dictionary should be interpreted as having meanings consistent with their meanings in the context of related literatures and will not be interpreted as having ideal or excessively formal meanings unless explicitly defined in the present application.

Meanwhile, one or more conventional components may be included in a configuration of the present disclosure if necessary, and such components will be described herein to an extent that it does not obscure the technical idea and concept of the present disclosure. If the description of the conventional components may obscure the technical idea and concept of the present disclosure, however, detailed description of such components may be omitted for simplicity.

However, it is not the intention of the present disclosure to claim rights over such prior art, and the content of the prior art may be included as part of the present disclosure to the extent that it does not depart from the spirit of the disclosure.

Hereinafter, exemplary embodiments of the present disclosure will now be described in detail with reference to the accompanying drawings. In the drawings, the same components may be designated by the same reference numerals to facilitate overall understanding of the disclosure, and duplicate descriptions thereof will be omitted for simplicity.

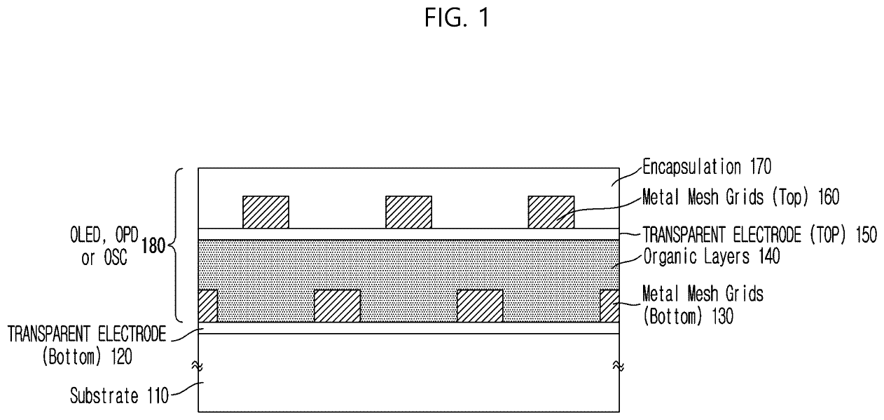

FIG. 1 is a conceptual diagram illustrating a semiconductor device having a metal grid according to exemplary embodiments of the present disclosure.

As shown in FIG. 1, the semiconductor device having a metal grid according to the present exemplary embodiment may include a metal material layer deposited in a predetermined mesh pattern with a plurality of openings formed on one surface of a transparent base member.

The material layer of the metal mesh grid may include any one selected from the group consisting of gold, silver, copper, aluminum, magnesium, and alloys thereof.

As shown in FIG. 1, a semiconductor device structure according to exemplary embodiments of the present disclosure may include a substrate 110, a bottom transparent electrode 120, a bottom mesh metal grid 130, organic layers 140, a top transparent electrode 150, a top mesh metal grid 160, and/or an encapsulation layer 170 for moisture resistance. In addition, the semiconductor device structure 180 including the bottom transparent electrode 120, the bottom mesh metal grid 130, the organic layers 140, the top transparent electrode 150, the top mesh metal grid 160, and the encapsulation layer 170 for moisture resistance may refer to at least one of an OLED, an OPD (Organic Photo Detector), and/or an OSC (Organic Solar Cell).

The semiconductor device may include at least one of an OLED device, an OPD device, and/or an OSC device. Although FIG. 1 illustrates exemplary embodiments in which the substrate 110, the bottom transparent electrode 120, the bottom mesh metal grid 130, the organic layers 140, the top transparent electrode 150, the top mesh metal grid 160, and the encapsulation layer 170 for moisture resistance are sequentially arranged as the components of the semiconductor device, the scope of the present disclosure is not limited thereto. In other exemplary embodiments of the present disclosure, variations in the transparent electrodes 120 and 150 and the mesh metal grids 130 and 160 are possible.

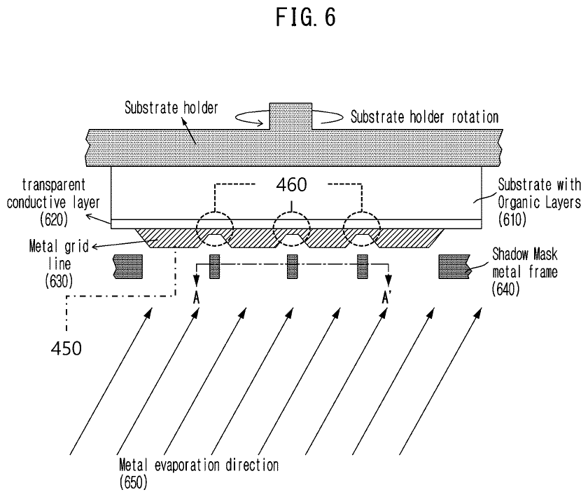

In the present exemplary embodiment, the substrate 110 may include at least one of a semiconductor substrate, a metal substrate, a glass substrate, and/or a flexible substrate. The flexible substrate may include at least one of polymer substrates, for example, polyethylene terephthalate (PET) and/or polyimide (PI). Specifically, the substrate 110 may include at least one of glass, PET film, and/or a transparent material formed on glass or PET film. When the transparent material is pre-formed, the bottom transparent electrode 120 may be omitted. For convenience for the explanation, a transparent base member may refer to the substrate 110, a transparent film/electrode/conductive layer (refer to 620 of FIG. 6) on the substrate 110 (or 610 of FIG. 6), and/or the both of the substrate 110 and the layer 620 Meanwhile, the substrate 110 may include a material layer having conductivity. In the present disclosure, it may be preferable that the substrate 110 has a thickness of 6 nm to 20 nm. At least one of a bottom transparent electrode and/or a bottom mesh metal grid may be formed on the substrate 110.

The bottom transparent electrode 120 may include at least one of metal materials selected from the group consisting of gold, silver, copper, aluminum, magnesium, and alloys of these metal elements, or may include at least one of transparent oxides (TCOs) selected from the group consisting of indium tin oxide (ITO), antimony tin oxide (ATO), zinc oxide (ZnO), tin oxide (SnO₂), indium zinc oxide (IZO), gallium zinc oxide (GZO), aluminum-doped zinc oxide (AZO), and/or cadmium tin oxide (CTO). In addition, the bottom transparent electrode 120 may include at least one of Ag nanowires and/or graphene.

In this case, the bottom transparent electrode 120 in the present exemplary embodiment may have a thickness of about 6 nm to 20 nm and may preferably be formed to have a sheet resistance of 25 ohm/sq. to 500 ohm/sq. (Ω/□).

At least one of the bottom mesh metal grid 130 and/or the organic layers 140 may be formed on the bottom transparent electrode 120.

The bottom mesh metal grid 130 may be a component deposited in a predetermined mesh pattern with a plurality of openings formed on one surface of the substrate 110 and may include a material having conductivity. In this case, the bottom mesh metal grid 130 may have various mesh shapes and may be formed on one surface of at least one of the substrate 110 and/or the bottom transparent electrode 120. The bottom mesh metal grid 130 may include a material having excellent conductivity.

In this case, the bottom mesh metal grid 130 may have a thickness of 20 nm to 500 nm and may preferably be formed to have a sheet resistance of 5 ohm/sq. to 50 ohm/sq., which is desirable for ensuring sufficient conductivity. Also, it may be preferable that the bottom mesh metal grid 130 has a width of 50 μm to 1.0 mm to facilitate the process and to maintain high transmittance and conductivity.

In the present exemplary embodiment, the bottom mesh metal grid 130 may specifically include at least one selected from the group consisting of gold, silver, copper, aluminum, magnesium, or alloys of these metal elements. The bottom mesh metal grid 130 may be formed of a metal material having excellent conductivity. At least one of the bottom transparent electrode 120 and/or the organic layers 140 may be formed on one surface of the bottom mesh metal grid 130.

At least one of the top transparent electrode 150 and/or the top mesh metal grid 160 may be formed on one surface of the organic layers 140.

The top transparent electrode 150 may be formed on the organic layers 140 constituting an OLED, OPD, or OSC. The top transparent electrode 150 may include at least one of metal materials selected from the group including gold, silver, copper, aluminum, magnesium, or alloys of these metal elements, or may include at least one of transparent oxides (TCOs) selected from the group consisting of indium tin oxide (ITO), antimony tin oxide (ATO), zinc oxide (ZnO), tin oxide (SnO2), indium zinc oxide (IZO), gallium zinc oxide (GZO), aluminum-doped zinc oxide (AZO), and cadmium tin oxide (CTO). In addition, the top transparent electrode 150 may include at least one of Ag nanowires or graphene.

In this case, the top transparent electrode 150 in the present exemplary embodiment may have a thickness of about 6 nm to 20 nm and may preferably be formed to have a sheet resistance

### Of 25 Ohm/sq. to 500 Ohm/sq. (Ω/□).

The top mesh metal grid 160 may include a material having excellent conductivity. In the present exemplary embodiment, the top mesh metal grid 160 may be formed in a layered manner on one surface of at least one of the organic layers 140 and/or the top transparent electrode 150.

In this case, the top mesh metal grid 160 in the present exemplary embodiment may have a thickness of 20 nm to 500 nm and may preferably be formed to have a sheet resistance of 5 ohm/sq. to 50 ohm/sq., which is desirable for ensuring sufficient conductivity. Also, it may be preferable that the top mesh metal grid 160 has a width of 50 μm to 1.0 mm to facilitate the process and to maintain high transmittance and conductivity.

In the present exemplary embodiment, the top mesh metal grid 160 may specifically be any one selected from the group consisting of gold, silver, copper, aluminum, magnesium, and/or alloys of these metal elements, which may be advantageous for ensuring excellent conductivity.

The top mesh metal grid 160 may be deposited in a predetermined mesh pattern with a plurality of openings formed on one surface of at least one of the top transparent electrode 150 and/or the organic layers 140 and may include a material having conductivity.

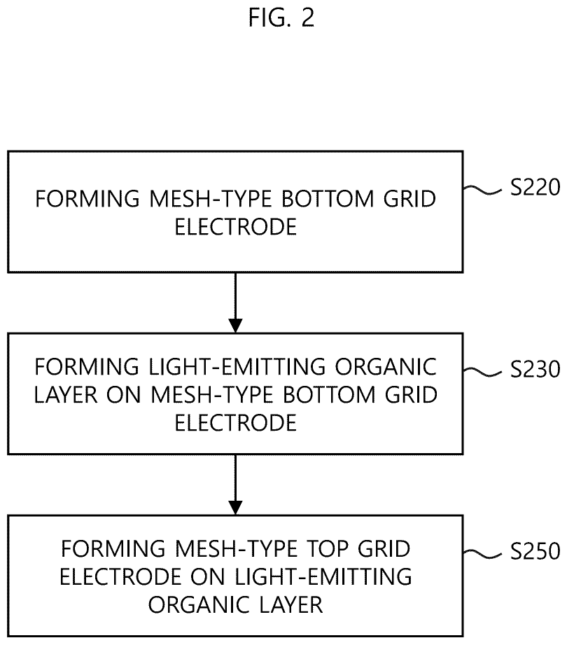

FIG. 2 is a flowchart illustrating a method of manufacturing a semiconductor device having a metal grid according to exemplary embodiments of the present disclosure. The method of manufacturing a semiconductor device according to exemplary embodiments of the present disclosure may include forming a mesh-type bottom grid electrode (in step S220), forming a light-emitting organic layer on the mesh-type bottom grid electrode (in step S230), and forming a mesh-type top grid electrode on the light-emitting organic layer (in step S250).

In step S220 or S250 of forming the grid electrode, the material layer of the grid may include at least one of gold, silver, copper, aluminum, magnesium, and/or alloys thereof.

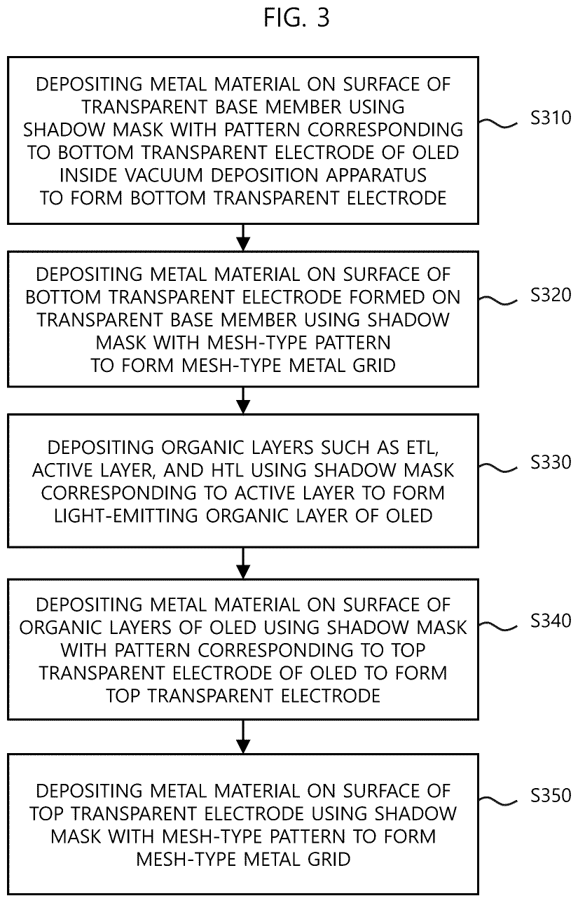

FIG. 3 is a flowchart illustrating a method of manufacturing a semiconductor device having a metal grid according to other exemplary embodiments of the present disclosure. The method of manufacturing a semiconductor device according to exemplary embodiments of the present disclosure may include depositing a metal material on a surface of a transparent base member using a shadow mask with a pattern corresponding to a bottom transparent electrode of an OLED inside a vacuum deposition apparatus to form the bottom transparent electrode (in step S310); depositing a metal material on a surface of the bottom transparent electrode formed on the transparent base member using a shadow mask with mesh-type pattern to form a mesh-type metal grid (in step S320); depositing organic layers such as an ETL, an active layer, and an HTL and so on, on the mesh-type metal grid and open area exposed through the mesh-type metal grid using a shadow mask corresponding to an active layer and so on to form a light-emitting organic layer of the OLED (in the step S330); depositing a metal material on a surface of the organic layers of the OLED using a shadow mask with a pattern corresponding to a top transparent electrode of an OLED to form the top transparent electrode (in step S340); or depositing a metal material on a surface of the top transparent electrode using a shadow mask with mesh-type pattern to form a mesh-type metal grid (in step S350).

The order of at least one of the steps including depositing a metal material on a surface of a transparent base member using a shadow mask with a pattern corresponding to a bottom transparent electrode of an OLED inside a vacuum deposition apparatus to form the bottom transparent electrode (in step S310); depositing a metal material on a surface of the bottom transparent electrode formed on the transparent base member using a shadow mask with mesh-type pattern to form a mesh-type metal grid (in step S320); depositing organic layers such as an ETL, an active layer, and an HTL on the mesh-type metal grid and open area exposed through the mesh-type metal grid using a shadow mask to form a light-emitting organic layer of the OLED (in the step S330); depositing a metal material on a surface of the organic layers of the OLED using a shadow mask with a pattern corresponding to a top transparent electrode of an OLED to form the top transparent electrode (in step S340); or depositing a metal material on a surface of the top transparent electrode using a shadow mask with mesh-type pattern to form a mesh-type metal grid (in step S350), may be changed.

In other exemplary embodiments of the present disclosure, when a transparent material is pre-formed before the bottom transparent electrode 110 is formed, the step of depositing of the metal layer to form the bottom transparent electrode 110 (step 310) may be omitted.

In depositing a metal material on a surface of a transparent base member using a shadow mask with a pattern corresponding to a bottom transparent electrode of an OLED inside a vacuum deposition apparatus to form the bottom transparent electrode (in step S310), the bottom transparent electrode may be an anode electrode. In addition, the bottom transparent electrode may be formed on a surface of the metal grid.

In depositing a metal material on a surface of the bottom transparent electrode formed on the transparent base member using a shadow mask with mesh-type pattern to form a mesh-type metal grid (in step S320), the mesh-type metal grid may be formed on a surface of the transparent base member.

In depositing organic layers such as an ETL, an active layer, and an HTL on the mesh-type metal grid using a shadow mask to form a light-emitting organic layer of the OLED (in the step S330), the organic layers may be formed on a surface of at least one of the transparent base member and/or the bottom grid electrode. In addition, in step S330, the shadow mask may have a pattern corresponding to the active layer of the OLED.

In depositing a metal material on a surface of the organic layers of the OLED using a shadow mask with a pattern corresponding to a top transparent electrode of an OLED to form the top transparent electrode (in step S340), the top transparent electrode may be a cathode electrode. In addition, in step S340, the shadow mask may have a pattern corresponding to the cathode electrode.

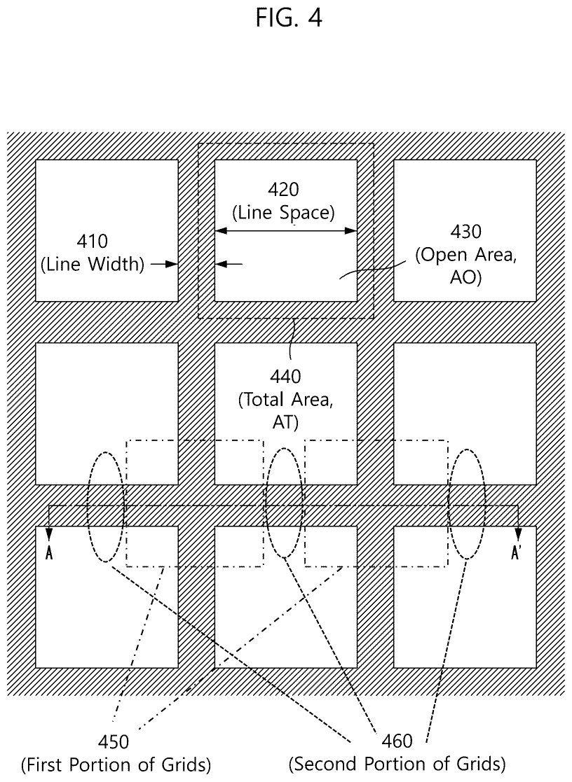

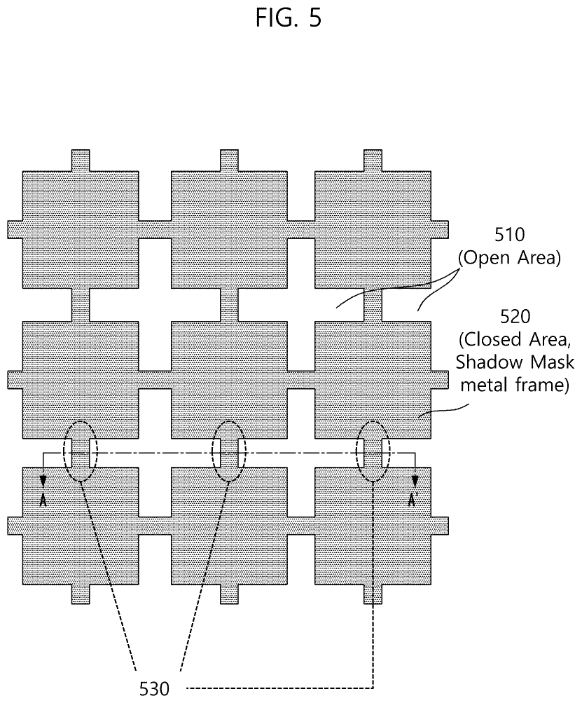

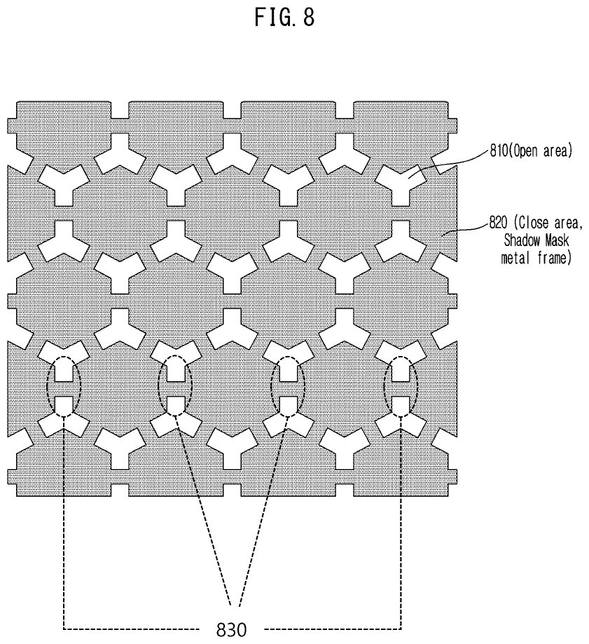

FIG. 4 is a plan view showing a state in which mesh-type metal grid patterns are formed on a transparent base member according to exemplary embodiments of the present disclosure. By depositing a metal material via an evaporation method inside a vacuum chamber using a shadow mask having a separated mesh pattern placed above the transparent base member (as will be described later in FIG. 5 and FIG. 8), the mesh patterns deposited on the member may be formed as a metal grid in a structure where the patterns are connected to each other.

The line width 410 of the mesh metal grid pattern may be the distance between mesh patterns. The line space 420 between the metal lines of the mesh metal grid may be the length of the mesh pattern. The open area AO 430 may be a region where the grid electrode is not formed on the substrate or the transparent electrode. The total area A_{T} 440 may be the area of one mesh unit.

In the present exemplary embodiments, the aperture ratio of the mesh metal grid 130 formed on the substrate 110 or the transparent electrode 120 may preferably be 50% or more. Here, the aperture ratio refers to the ratio of the area of the open region AO 430 within one mesh to the total mesh area A_{T} 440, as shown in FIG. 4. The mesh aperture ratio may be defined as AO/A_{T}×100%.

When the mesh aperture ratio defined in this way is 50% or more, excellent light transmittance and conductivity comparable to conventional methods can be secured, which may be desirable. The mesh metal grid pattern may have a line width of 10 μm to 1.0 mm and a thickness of 10 nm to 10 μm. The line space 420 between metal lines of the mesh metal grid according to the present disclosure may preferably be 100 μm to 1.0 mm in order to ensure that the mesh aperture ratio is 50% or more.

FIG. 5 is a plan view illustrating the structure of a mesh-type grid pattern of a shadow mask according to exemplary embodiments of the present disclosure. The open region/area 510 of the shadow mask may be a region where the shadow mask is absent and the material below the mask is exposed. The closed region/area 520 of the shadow mask may be understood as any one of the shadow mask itself or a region covered by the shadow mask.

FIG. 6 is a cross-sectional view illustrating examples of a method of depositing a metal material using a shadow mask inside a vacuum chamber to form a metal grid according to exemplary embodiments of the present disclosure. The light-emitting organic layer 610 may be formed as at least one of an OLED, OPD, and/or OSC. The transparent electrode layer 620 may include at least one of metal materials selected from the group consisting of gold, silver, copper, aluminum, magnesium, or alloys of these metal elements, or may include at least one of transparent oxides (TCOs) selected from the group consisting of indium tin oxide (ITO), antimony tin oxide (ATO), zinc oxide (ZnO), tin oxide (SnO₂), indium zinc oxide (IZO), gallium zinc oxide (GZO), aluminum-doped zinc oxide (AZO), and cadmium tin oxide (CTO).

In the exemplary embodiment of FIG. 6, the metal grid 630 represents a top metal grid electrode formed after the formation of the light-emitting organic layer 610. However, in other exemplary embodiments of the present disclosure, the process of forming a bottom metal grid electrode before forming the light-emitting organic layer 610 may also be carried out using a process similar to that of FIG. 6.

The metal grid 630 may be formed as a first portion 450 of the grid electrode formed on a first partial region of a first surface through the open region 510 of the shadow mask, such as that shown in FIG. 5, and a second portion 460 of the grid electrode formed on a second partial region of the first surface covered by a connecting portion 530 between patterns of the closed region 520 of the shadow mask.

In other words, the second portion 460 of the grid electrode may be formed/deposited by infiltrating/penetrating into the second partial region of the first surface under the connecting portion 530 despite the covering of the connecting portion 530. The first portion 450 may be one part of the grid and may form the grid point portion of the lattice structure of the grid, as shown in FIG. 5. On the other hand, the second portion 460 may be another part of the grid and may form a connection part connecting the grid point portion of the lattice structure of the grid.

In addition, the metal grid 630 formed by such a process may have an inclined surface in the boundary region between the first portion 450 and the second portion 460, as shown in FIG. 6.

Meanwhile, the first surface, described above, may refer to a surface of at least one of a transparent base member, a transparent electrode, and/or an organic layer. That is, the term “first surface” is introduced for convenience of explanation, and refers to the surface facing the shadow mask 640 and on which the metal grid 630 is formed.

As shown in FIG. 6, when the metal grid 630 is a top grid electrode, in step S250 or S350 of forming the top grid electrode, the first surface may refer to at least one of the light-emitting organic layer 140, 610 and the top transparent electrode 150, 620.

In other exemplary embodiments of the present disclosure, when the metal grid 630 is assumed to be a bottom grid electrode, in step S220 or S320 of forming the bottom grid electrode, the first surface may refer to at least one of the substrate 110 or the bottom transparent electrode 120 as the transparent base member.

The shadow mask metal frame 640 may have various pattern shapes such as rectangular, diamond, or honeycomb structures. The scope of the present disclosure is not limited to exemplary embodiments having specific pattern shapes. In other exemplary embodiments of the present disclosure, the shadow mask metal frame 640 may have a structure in which multiple pattern shapes are combined.

The metal evaporation direction 650 may refer to the direction (inclination or angle) at which the metal material is incident with respect to the shadow mask. The metal evaporation direction 650 may be changed depending on the exemplary embodiment.

Referring to FIGS. 4, 5, and 6 together, the shadow mask in FIG. 5 is represented as the shadow mask metal frame 640 in FIG. 6. Since the metal material is deposited onto the first surface through the open region 510 of the shadow mask in FIG. 5, a first portion 450 forming the grid structure of the metal mesh grid in FIG. 4 may be formed.

A relatively small amount of metal material may be deposited on the first surface beneath the connecting portion 530 between closed regions 520 of the shadow mask by penetrating/infiltrating into the first surface under the connecting portion 530 in FIG. 5. In this case, the amount of metal material deposited (forming the second portion 460) on the surface region covered by the connecting portion 530 may be controlled based on the spacing between the shadow mask 640 and the first surface (transparent conductive layer 620 in FIG. 6) and the direction (inclination or angle) of the metal evaporation direction 650.

As a result, a second portion 460 of the metal mesh grid connecting the first portions 450 may be formed on the surface region covered by the connecting portion 530 (despite the covering of the connecting portion 530). Referring to FIG. 4, the first portion 450 may represent a part forming the grid point portion of the grid structure of the metal mesh grid, and the second portion 460 may represent a connecting part connecting the first portions 450 to secure connectivity and conductivity of the metal mesh grid.

When the metal evaporation direction 650 is perpendicular to the first surface, the deposition material (for example, metal material) may penetrate/infiltrate under the connecting portion 530 of the shadow mask and be deposited on the first surface under the connecting portion 530 of the shadow mask based on (a) the separation distance between the transparent conductive layer 620 and the shadow mask 640 and (b) the line width 410 of the pattern formed through the opening width of the shadow mask.

As a result, the metal pattern may form a second portion 460 connecting adjacent first portions 450 (forming grid point portion of the lattice structure) of the metal mesh grid of FIG. 4. The direction (inclination/angle) of the metal evaporation direction 650 may also be controlled as one of the parameters of the manufacturing process for forming the second portion 460.

The first portion 450 may correspond to the protruded part of the metal grid 630 in FIG. 6, and the second portion 460 may correspond to the recessed part of the metal grid 630 in FIG. 6. The first portion 450, as the protruded part of the metal grid 630, may have a first thickness. The second portion 460, as the recessed part of the metal grid 630, may have a second thickness. The second thickness may be smaller than the first thickness, as shown in FIG. 6.

In the present disclosure, the first portions 450 and the second portions 460 may be deposited/formed together on the same surface (i.e., the first surface), as shown in FIG. 6.

In the present disclosure, the first portions 450 and the second portions 460 may be deposited/formed together in the same deposition process, as shown in FIG. 6.

In the present disclosure, the first portions 450 and the second portions 460 may be deposited/formed together using the same shadow mask 640, as shown in FIG. 6.

In the present disclosure, the first portions 450 and the second portions 460 may be deposited/formed with the same materials on the same surface since the first portions 450 and the second portions 460 are deposited in the same deposition process.

In the present disclosure, the first portions 450 and the second portions 460 may be deposited/formed with the same materials on the same surface but only have different thicknesses since the first portions 450 and the second portions 460 are deposited in the same deposition process while only under the different topology relative to the shadow mask 640.

Due to the physical characteristics of the shadow mask 640 on the substrate or the first surface, the distance between the first surface and the shadow mask 640 may be smaller in the edge region and larger in the central region. In the exemplary embodiment of the present disclosure, the spacing may be predicted based on the relative position on the flat panel (whether it is closer to the center or the edge), and the shape of the metal grid 630 may be controlled according to target physical and electrical characteristics of the metal grid 630.

According to other exemplary embodiments of the present disclosure, various forms of shadow masks may be introduced to form metal mesh grids of various shapes.

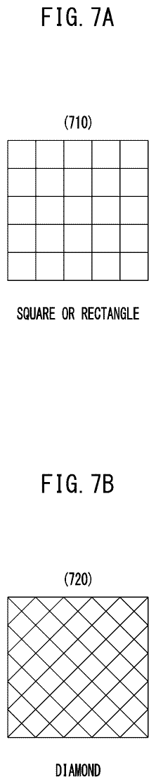

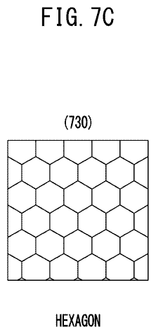

FIGS. 7A, 7B and 7C are conceptual diagrams respectively illustrating examples of mesh shapes including rectangular, diamond, and hexagonal honeycomb structures according to exemplary embodiments of the present disclosure. Referring to FIGS. 7A, 7B and 7C, the shadow mask may have at least one pattern selected from a rectangular pattern 710, a diamond pattern 720, and/or a hexagon/honeycomb structure 730.

FIG. 8 is a plan view illustrating a pattern structure of a shadow mask for forming a hexagonal honeycomb metal grid according to exemplary embodiments of the present disclosure, as shown in FIG. 7C. The open region/area 810 of the shadow mask may refer to a portion where the surface below the mask is exposed due to the absence of the shadow mask. The closed region/area 820 of the shadow mask may refer to the shadow mask itself, or to a portion where the surface below the shadow mask is covered by the shadow mask.

As in the exemplary embodiments of FIGS. 4 through 6, when the exemplary embodiment of FIG. 8 is combined with the exemplary embodiment of FIG. 6, a metal mesh grid of the hexagon/honeycomb structure 730 in FIG. 7C may be implemented.

In the exemplary embodiment of FIG. 8, as the hexagonal pattern embodiment, the mesh metal grid may be deposited/formed into the covered area by the connected portion 830 by penetrating/infiltrating into the covered portion of the surface, in a similar way to the disclosure shown by FIGS. 4, 5, and 6.

In this case, the metal mesh grid of the hexagon/honeycomb structure 730 may form a lattice and may include a first portion (similar to the first portion 450) having a first thickness, and a second portion (similar to the second portion 460) having a second thickness smaller than the first thickness and connecting the first portions.

In this case, the first portions and the second portions of mesh grid structure 730, formed together in the same deposition process using the shadow mask exemplarily shown in FIG. 8, may be formed with the same materials on the same surface but only have different thicknesses since the first portions and the second portions of mesh grid structure 730, are deposited in the same deposition process while only under the different topology relative to the shadow mask exemplarily shown in FIG. 8.

Similarly, the grid patterns 710 and 720 may have the first portions and the second portions, respectively, formed together in the same deposition process using a shadow mask, may be formed with the same materials on the same surface but only have different thicknesses since the first portions and the second portions of mesh grid structure 710 and 720, are deposited in the same deposition process while only under the different topology relative to the shadow mask.

While the present disclosure has been described with reference to preferred embodiments, it will be understood by those skilled in the art that various modifications and changes may be made without departing from the spirit and scope of the invention as defined in the appended claims.

What is claimed is:

1. A semiconductor device, comprising:
a transparent base member;
a bottom grid electrode formed on the transparent base member;
a light-emitting organic layer formed on the bottom grid electrode; and
a top grid electrode formed on the light-emitting organic layer,
wherein at least one of the bottom grid electrode or the top grid electrode is a mesh-type electrode, and
wherein at least one of the bottom grid electrode or the top grid electrode comprises:
a plurality of first portions forming a grid point portion and having a first thickness; and
a second portion having a second thickness smaller than the first thickness and connecting the first portions.

2. The semiconductor device according to claim 1, wherein the first portions and the second portions are formed with the same materials.

3. The semiconductor device according to claim 1, wherein the first portions and the second portions are formed on a same surface.

4. The semiconductor device according to claim 1, wherein at least one of the bottom grid electrode or the top grid electrode has at least one pattern of a rectangular pattern, a diamond pattern, or a hexagonal pattern.

5. The semiconductor device according to claim 1, wherein at least one of the bottom grid electrode or the top grid electrode has an inclined surface at a boundary region between the first portions and the second portions.

6. The semiconductor device according to claim 1, wherein the transparent base member is at least one of a substrate or a transparent conductive layer.

7. A method of manufacturing a semiconductor device, comprising:
forming a bottom grid electrode on a transparent base member;
forming a light-emitting organic layer on the bottom grid electrode; and
forming a top grid electrode on the light-emitting organic layer,
wherein at least one of the forming of the bottom grid electrode or the forming of the top grid electrode is performed such that at least one of the bottom grid electrode or the top grid electrode is formed as a mesh-type electrode, and
wherein at least one of the forming of the bottom grid electrode or the forming of the top grid electrode is performed using a deposition process in which a metal material is deposited using a shadow mask having a mesh pattern.

8. The method of manufacturing a semiconductor device according to claim 7, wherein at least one of the forming of the bottom grid electrode or the forming of the top grid electrode is performed so as to comprise a plurality of first portions forming a grid point portion and having a first thickness, and a second portion having a second thickness smaller than the first thickness and connecting the first portions.

9. The method of manufacturing a semiconductor device according to claim 8, wherein the first portions and the second portions are formed with the same materials.

10. The method of manufacturing a semiconductor device according to claim 8, wherein the first portions and the second portions are formed on a same surface.

11. The method of manufacturing a semiconductor device according to claim 8, wherein the first portions and the second portions are formed together in a same deposition process.

12. The method of manufacturing a semiconductor device according to claim 7, wherein the shadow mask having the mesh pattern has a frame pattern for forming a grid electrode having at least one pattern of a rectangular structure, a diamond structure, or a honeycomb structure.

13. The method of manufacturing a semiconductor device according to claim 7, wherein at least one of the forming of the bottom grid electrode or the forming of the top grid electrode is performed in a state in which a metal evaporation direction of the metal material is controlled to be inclined with respect to the shadow mask.

14. The method of manufacturing a semiconductor device according to claim 7, wherein at least one of the forming of the bottom grid electrode or the forming of the top grid electrode is performed such that at least one of the bottom grid electrode or the top grid electrode is formed on a first partial region of a first surface exposed by the shadow mask and a second partial region covered by a connecting portion between patterns of the shadow mask.

15. The method of manufacturing a semiconductor device according to claim 14, wherein the first surface is at least one of the transparent base member or the light-emitting organic layer partially exposed by the shadow mask.

16. The method of manufacturing a semiconductor device according to claim 14, wherein at least one of the forming of the bottom grid electrode or the forming of the top grid electrode is performed in a state that the shadow mask is spaced apart at a distance from the first surface, such that deposition materials are infiltrated into the second partial region under the connecting portion of the shadow mask.

17. The method of manufacturing a semiconductor device according to claim 7, wherein the transparent base member is at least one of a substrate or a transparent conductive layer.
